(19) United States
(12) Patent Application Publication
(10) Pub. No.: US 2016/0100503 A1
(43) Pub. Date: Apr. 7, 2016

(54) SYSTEMS AND METHODS FOR COOLING A PROBE DISPOSED ABOUT A HOT GAS PATH

(71) Applicant: General Electric Company, Schenectady, NY (US)

(72) Inventors: Yamil Miguel Morales Valvieja, Greenville, SC (US); Michael Anthony Armocida, Greenville, SC (US); Joaquin Hiram Ayala Hernandez, Atlanta, GA (US); Andrea Booher Kretschmar, Simpsonville, SC (US); Miho Onuki, Houston, TX (US); Katherine Derksen Stinson, Redmond, WA (US); Kurt Kramer Schleif, Greenville, SC (US)

(73) Assignee: General Electric Company, Schenectady, NY (US)

(21) Appl. No.: 14/508,562

(22) Filed: Oct. 7, 2014

(51) Int. Cl. H05K 7/20; G01P 3/36; G01B 11/16; G01H 9/00; G01M 15/14; G01M 15/02

(52) U.S. Cl. CPC H05K 7/20009; G01M 15/14; G01M 15/02; G01B 11/16; G01H 9/00; G01P 3/36; H05K 7/20272

(57) ABSTRACT

A system for cooling a probe disposed about a hot gas path is disclosed herein. The system may include a probe holder having a main body including an inner passage, an intermediate passage, and an outer passage. The intermediate passage and the outer passage may be in fluid communication. The probe may be disposed within the inner passage of the probe holder. The probe may include an internal passage. The system also may include a first cooling circuit in fluid communication with internal passage of the probe. Moreover, the system may include a second cooling circuit having an inlet in fluid communication with the intermediate passage and an outlet in fluid communication with the outer passage.

### FIELD OF THE DISCLOSURE

The disclosure generally relates to a probe and a probe holder and more particularly relates to systems and methods for cooling a probe disposed about a hot gas path.

### BACKGROUND

Laser probes may be used to monitor one or more buckets in a turbine of a gas turbine engine. Laser probes may detect, among other things, bucket tip timing, deflection, speed, vibrations, and/or deformation. The first stage of a turbine is typically the hottest. As a result, laser probes disposed about the first stage must be cooled. However, current techniques for cooling laser probes may be inadequate and can result in unreliable data and/or equipment failure.

### SUMMARY

Some or all of the above needs and/or problems may be addressed by certain embodiments of the systems and methods disclosed herein. According to an embodiment, a system for cooling a probe disposed about a hot gas path is disclosed. The system may include a probe holder having a main body including an inner passage, an intermediate passage, and an outer passage. The intermediate passage and the outer passage may be in fluid communication. The probe may be disposed within the inner passage of the probe holder. The probe may include an internal passage. The system also may include a first cooling circuit in fluid communication with internal passage of the probe. Moreover, the system may include a second cooling circuit having an inlet in fluid communication with the intermediate passage and an outlet in fluid communication with the outer passage.

Other features and aspects of the probe and probe holder will be apparent or will become apparent to one with skill in the art upon examination of the following figures and the detailed description. All other features and aspects, as well as other system, method, and assembly embodiments, are intended to be included within the description and are intended to be within the scope of the accompanying claims.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 schematically depicts a system in accordance with one or more embodiments of the disclosure.

FIG. 2 schematically depicts a cross sectional view of a probe holder in accordance with one or more embodiments of the disclosure.

FIG. 3 schematically depicts a bottom view of a probe holder in accordance with one or more embodiments of the disclosure.

### DETAILED DESCRIPTION

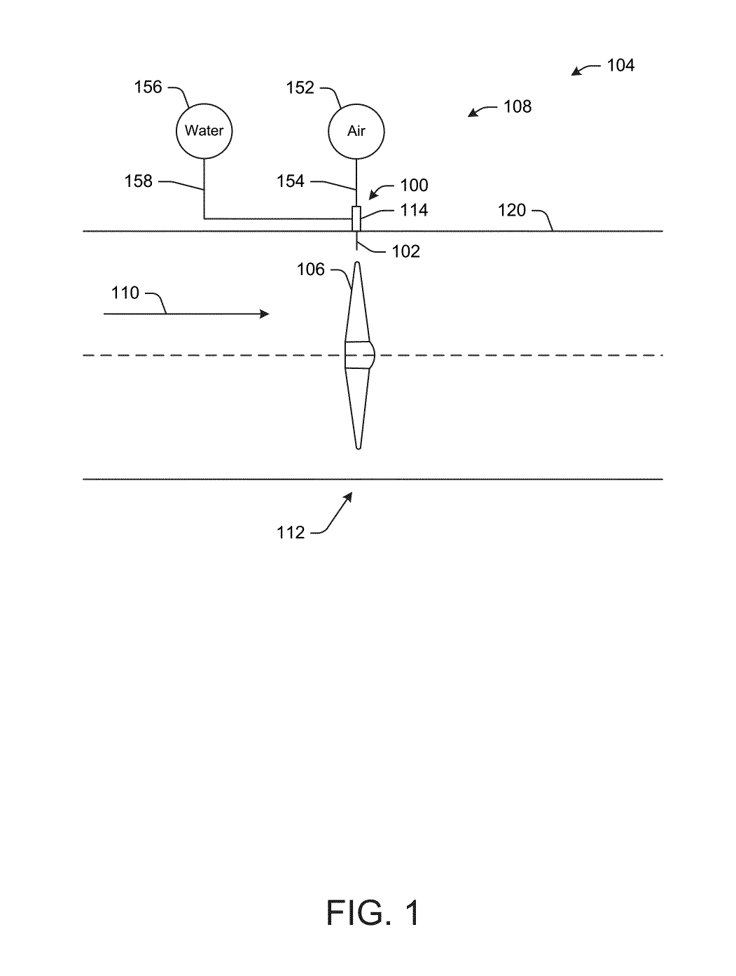

FIGS. 1-3 describe one or more embodiments of a probe holder 100 for holding and cooling a probe 102 in a gas turbine engine 104 or the like. In other instances, the probe holder 100 may be used with a steam turbine or the like. The probe holder 100 may be used in conjunction with any device that includes a hot gas path. The probe holder 100 may be used in any suitable environment.

In some instances, the probe 102 may be a laser probe. The laser probe 102 may be used to monitor one or more rotating buckets 106 in a turbine 108 of the gas turbine engine 104 or other types of turbine components. The laser probe 102 may detect, among other things, bucket tip timing, deflection, speed, vibrations, and/or deformation. The laser probe 102 may be disposed about a hot gas path 110 of the turbine 108 at a first stage 112 of the turbine 108. The laser probe 102, however, may be disposed at any stage of the turbine 108, such as at a second stage, a third, stage, a fourth stage, and so on. Other types of probes may be used herein. Moreover, the probe holder 100 may be disposed at other locations about the gas turbine engine 104 or other types of engines or devices that may include a hot gas path.

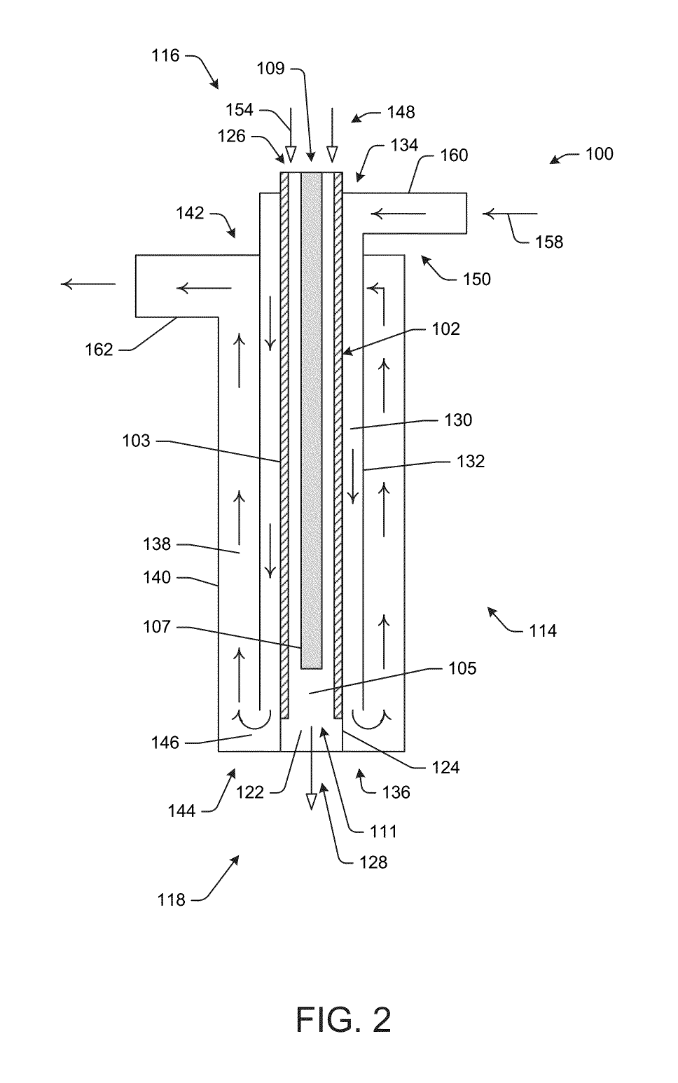

As depicted in FIG. 2, the laser probe 102 may include a laser probe body 103. In some instances, the laser probe body 103 may be tubular. The laser probe body 103 may include an internal laser probe passage 105. The internal laser probe passage 105 may include a first end 109 and a second end 111. In addition, the laser probe 102 may include an optics lens 107. In some instances, the optics lens 107 may be disposed within the internal laser probe passage 105. For example, the optics lens 107 may be disposed about a centerline of the laser probe body 103 within the internal laser probe passage 105. In some instances, the optics lens 107 may extend the length of the laser probe body 103 between the first end 109 and the second end 111 of the internal laser probe passage 105. In other instances, the optics lens 107 may be offset from the first end 109, the second end 111, or a combination thereof of the internal laser probe passage 105.

Still referring to FIG. 2, the probe holder 100 may include a main body 114. The main body 114 may include a first end 116 and a second end 118. In some instances, the second end 118 of the main body 114 may be disposed adjacent to the hot gas path 110 of the gas turbine engine 104. For example, the main body 114 may be attached to a turbine casing 120 or the like. In some instances, the second end 118 of the main body 114 may be disposed in line with the first stage 112 of the turbine 108. In this manner, the laser probe 102 may be positioned within the main body 114 and may monitor the buckets 106 rotating in the first stage 112.

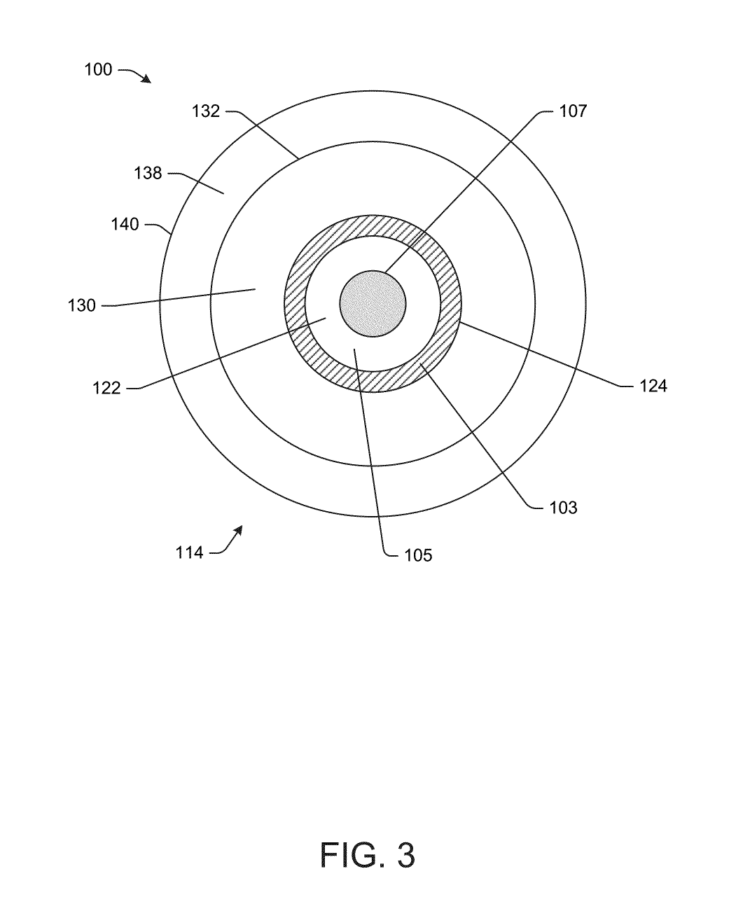

As depicted in FIGS. 2 and 3, the main body 114 may include an inner passage 122. The inner passage 122 may be formed by an inner wall 124. In some instances, the inner wall 124 may be tubular. The inner passage 122 may include a first end 126 and a second end 128. The laser probe 102 may be disposed within the inner passage 122. For example, an outer surface of the laser probe body 103 may be in contact with the inner wall 124. In some instances, the laser probe body 103 may extend from the first end 126 of the inner passage 122 to the second end 128 of the inner passage 122. In other instances, the laser probe body 103 may only partially extend between the first end 126 of the inner passage 122 and the second end 128 of the inner passage 122. For example, the laser probe body 103 may be offset from the second end 128 of the inner passage 122. The laser probe 102 may be secured within the inner passage 122 by any means known in the art. For example, the laser probe body 103 may be bolted, welded, adhered, fastened, or the like to the inner wall 124.

The main body 114 also may include an intermediate passage 130. The intermediate passage 130 may be formed between the inner wall 124 and an intermediate wall 132. In some instances, the intermediate wall 132 may be tubular. The intermediate passage 130 may include a first end 134 and a second end 136. The inner passage 122 and the intermediate passage 130 may be independent of each other. That is, in some instances, there are no passageways or opening between the inner passage 122 and the intermediate passage 130. In other instances, the inner passage 122 and the intermediate passage 130 may include one or more passages therebetween.

The main body 114 also may include an outer passage 138. The outer passage 138 may be formed between the intermediate wall 132 and an outer wall 140. In some instances, the outer wall 140 may be tubular. The outer passage 138 may include a first end 142 and a second end 144. In some instances, the inner passage 122 and the outer passage 138 may be independent of each other. That is, in some instances, there are no passageways or opening between the inner passage 122 and the outer passage 138. In contrast, the intermediate passage 130 and the outer passage 138 may be in fluid communication. For example, the second end 136 of the intermediate passage 130 and the second end 144 of the outer passage 138 may include an opening 146. The opening 146 may provide a passageway between the intermediate passage 130 and the outer passage 138.

The probe 102 may include a first cooling circuit 148, and the probe holder 102 may include a second cooling circuit 150. The first cooling circuit 148 and the second cooling circuit 150 may cool the laser probe 102 disposed within the probe holder 100. The first cooling circuit 148 and the second cooling circuit 150 may act as heat exchangers. The first cooling circuit 148 and the second cooling circuit 150 may operate concurrently or individually.

The first cooling circuit 148 may include a first source of cooling fluid 152 (as depicted in FIG. 1). In some instances, the first source of cooling fluid 152 may be air, such as compressed air and/or bleed air. Other types of cooling fluids may be used. The first cooling circuit 148 may be in fluid communication with the internal laser probe passage 105. In this manner, the first cooling circuit 148 may provide a first flow of cooling fluid 154 (e.g., air) to the internal laser probe passage 105. For example, the first flow of cooling fluid 154 may enter the first end 109 of the internal laser probe passage 105 and exit the second end 111 of the internal laser probe passage 105 into the hot gas path 110 of the gas turbine engine 104. The first flow of cooling fluid 154 may include a pressure greater than the hot gas path 110 so as to prevent the hot gasses from entering the inner passage 122 and/or the internal laser probe passage 105. In this manner, the first flow of cooling fluid 154 may pass through the internal laser probe passage 105 around the optics lens 107. The first flow of cooling fluid 154 may cool and/or clean the optics lens 107. In other instances, the first flow of cooling fluid 154 may pass and/or around the laser probe body 103 disposed within the inner passage 122, which may cool the laser probe 102.

The second cooling circuit 150 may include a second source of cooling fluid 156 (as depicted in FIG. 1). In some instances, the second source of cooling fluid 156 may be water. Other types of cooling fluids may be used, such as hydrogen, carbon dioxide, sulfur hexafluoride, ethylene glycol, diethylene glycol, propylene glycol, bentaine, polyalkylene glycol, refrigerants, and so on. The second cooling circuit 150 may provide a second flow of cooling fluid 158 (e.g., water) to the intermediate passage 130 and the outer passage 138. For example, the second cooling circuit 150 may include an inlet 160 in fluid communication with the intermediate passage 130. In some instances, the inlet 160 may be disposed about the first end 134 of the intermediate passage 130. Moreover, the second cooling circuit 150 may include an outlet 162 in fluid communication with the outer passage 138. In some instances, the outlet 162 may be disposed about the first end 134 of the outer passage 138.

The second cooling fluid 158 may enter the inlet 160 at the first end 134 of the intermediate passage 130 and travel to the second end 136 of the intermediate passage 130. At the second end 136 of the intermediate passage 130, the second flow of cooling fluid 158 may pass through the opening 146 between the intermediate passage 130 and the outer passage 138. The second flow of cooling fluid 158 may then travel from the second end 144 of the outer passage 138 to the first end 142 of the outer passage 138, where it may exit at the outlet 162. In this manner, a flow direction of the second cooling fluid 158 in the intermediate passage 130 may be opposite a flow direction of the second cooling flow 158 in the outer passage 138. The second cooling circuit 150 provides a two pass counter flow heat exchanger with the laser probe 102. It is noted that the second flow of cooling fluid 158 is never in direct contact with the laser probe 102. In some instances, additional passages and walls may be incorporated into the probe holder 100 to provide additional counter flows. For example, the second cooling circuit 150 may include a number of counter flow heat exchangers.

In use, the first cooling circuit 148 and/or the second cooling circuit 150 maintain the laser probe 102 temperature within acceptable operating limits. Air 154 flows about the optics lens 107 within internal laser probe passage 105 and purges into the hot gas path 110. That is, the air 154 is directed through the internal laser probe passage 105 of the laser probe 102, where forced convection may remove heat form the laser probe 102. The air 154 then exits into the hot gas path 110. The air pressure is kept above the hot gas path pressures to prevent the ingestion of high temperature gasses into the internal laser probe passage 105 and/or the internal passage 122. Water 158 or other fluids may enter the intermediate passage 130 at the inlet 160 and flow down the intermediate passage 130 parallel to the flow within the internal laser probe passage 105 (to remove heat from the laser probe 102) until the water 158 reaches the second end 136 (or tip) of the intermediate passage 130. At the second end 136 of the intermediate passage 130, the water 158 is turned 180 degrees in the opposite direction at the opening 146, where it flows up the outer passage 138 parallel to the incoming water in the intermediate passage 130 but in the opposite direction. The water 158 in the outer passage 138 may remove heat from the surroundings and turn 90 degrees to exit at the outlet 162. The water 158 is never in direct contact with the laser probe 102 and/or the surrounding components. Water pressure and flow rate may be controlled to keep the water 158 from evaporating or flashing and to maintain the laser probe temperatures below the operating limit.

In some instances, due to the high temperatures of the hot has path 110, a layer of Thermal Barrier Coating (TBC) may be applied to the second end 118 of the main body 114 where the hot gas path 110 may come into contact. The TBC may reduce the thermal gradient along the main body 114 and reduce the heat being transferred to the water 158.

Although specific embodiments of the disclosure have been described, numerous other modifications and alternative embodiments are within the scope of the disclosure. For example, any of the functionality described with respect to a particular device or component may be performed by another device or component. Further, while specific device characteristics have been described, embodiments of the disclosure may relate to numerous other device characteristics. Further, although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A system for cooling a probe disposed about a hot gas path, the system comprising:
a probe holder comprising a main body comprising an inner passage, an intermediate passage, and an outer passage, wherein the intermediate passage and the outer passage are in fluid communication;
the probe being disposed within the inner passage of the probe holder, wherein the probe comprises an internal passage;
a first cooling circuit in fluid communication with internal passage of the probe; and
a second cooling circuit comprising an inlet in fluid communication with the intermediate passage and an outlet in fluid communication with the outer passage.

2. The system of claim 1, further comprising a first flow of cooling fluid in the first cooling circuit.

3. The system of claim 2, wherein the first flow of cooling fluid comprises air.

4. The system of claim 1, further comprising a second flow of cooling fluid in the second cooling circuit.

5. The system of claim 4, wherein the second flow of cooling fluid comprises water.

6. The system of claim 1, wherein the inner passage is formed by an inner wall, the intermediate passage is formed between the inner wall and an intermediate wall, and the outer passage is formed between the intermediate wall and an outer wall.

7. The system of claim 1, wherein the first cooling circuit exits into the hot gas path.

8. The system of claim 1, wherein the second cooling circuit comprises a two pass counter flow comprising a flow direction in the intermediate passage that is opposite a flow direction in the outer passage.

9. The system of claim 8, wherein a transition between the flow direction in the intermediate passage and the flow direction in the outer passage is at an end of the main body disposed adjacent to the hot gas path.

10. The system of claim 8, wherein the flow direction in the intermediate passage is the same as a flow direction in the internal passage of the probe.

11. The system of claim 1, wherein the probe comprises a laser probe.

12. The system of claim 1, wherein the inlet and the outlet of the second cooling circuit are spaced apart from an end of the main body disposed adjacent to the hot gas path.

13. A method for cooling a probe disposed about a hot gas path, the method comprising:
positioning the probe within an inner passage of a probe holder;
providing a first flow of cooling fluid within an internal passage of the probe; and
providing a second flow of cooling fluid within an intermediate passage and an outer passage of the probe holder.

14. A system for cooling a probe disposed about a hot gas path, the system comprising:
a first flow of cooling fluid;
a second flow of cooling fluid;
a probe holder comprising a main body having an inner passage, an intermediate passage, and an outer passage, wherein the intermediate passage and the outer passage are in fluid communication;
the probe being disposed within the inner passage of the probe holder, wherein the probe comprises an internal passage;
a first cooling circuit in fluid communication with the internal passage of the probe and the first flow of cooling fluid; and
a second cooling circuit in fluid communication with the second flow of cooling fluid and comprising an inlet in fluid communication with the intermediate passage and an outlet in fluid communication with the outer passage.

15. The system of claim 14, wherein the first flow of cooling fluid comprises air.

16. The system of claim 14, wherein the second flow of cooling fluid comprises water.

17. The system of claim 14, wherein the inner passage is formed by an inner wall, the intermediate passage is formed between the inner wall and an intermediate wall, and the outer passage is formed between the intermediate wall and an outer wall.

18. The system of claim 14, wherein the first cooling circuit exits into the hot gas path.

19. The system of claim 14, wherein the second cooling circuit comprises a two pass counter flow comprising a flow direction in the intermediate passage that is opposite a flow direction in the outer passage.

20. The system of claim 14, wherein the probe comprises a laser probe.
